(19) United States
(12) Patent Application Publication
(10) Pub. No.: US 2023/0217723 A1
(43) Pub. Date: Jul. 6, 2023

(54) DISPLAY DEVICE

(71) Applicant: LG Display Co., Ltd., Seoul (KR)

(72) Inventors: KyungKook JANG, Paju-si (KR); SeongHan HWANG, Paju-si (KR); DaBin KIM, Paju-si (KR); Wonrae KIM, Paju-si (KR)

(73) Assignee: LG Display Co., Ltd., Seoul (KR)

(21) Appl. No.: 17/982,159

(22) Filed: Nov. 7, 2022

(30) Foreign Application Priority Data
Dec. 31, 2021 (KR) 10-2021-0194563

(51) Int. Cl. H01L 27/32; H01L 51/52; C09K 11/88; C09K 11/08

(52) U.S. Cl. CPC H01L 27/3246; H01L 51/5284; C09K 11/883; C09K 11/0883; H01L 27/3227; B82Y 20/00

(57) ABSTRACT

A display device can include a substrate including a display area, a subpixel positioned on the substrate and positioned in the display area, and a black bank positioned on the substrate. The black bank can include a first opening corresponding to an emission area of the subpixel, and quantum dots that absorb light having a wavelength in a visible light region. As a result, the display device can reduce external light reflectance.

### CROSS-REFERENCE TO RELATED APPLICATION

This application claims priority to Korean Patent Application No. 10-2021-0194563, filed in the Republic of Korea on Dec. 31, 2021, the entire contents of which are hereby incorporated by reference into the present application.

### BACKGROUND OF THE INVENTION

### 1. Field of the Invention

Embodiments of the present disclosure relate to a display device.

### 2. Description of the Related Art

A display device is needed to have a low reflectance with respect to external light such that a user can easily identify information displayed on the display device even under a condition in which the external light is present.

A display device can include various circuit elements to display an image. When external light is radiated onto the display device, light can be reflected from the circuit elements included in the display device, and thus it can be difficult for a user to identify information displayed on the display device.

### SUMMARY OF THE INVENTION

A display device can include a plurality of transparent layers capable of transmitting light to increase efficiency. However, when the transparent layer is used, light can be reflected by circuit elements included in the display device, and thus it can be difficult for a user to identify information displayed on the display device.

Accordingly, the inventors of the present disclosure have invented a display device capable of reducing external light reflectance by including a black bank which includes quantum dots that absorb light having a wavelength in a visible light region.

An aspect of the present disclosure is to provide a display device which addresses the limitations associated with the related art.

An aspect of the present disclosure is to provide a display device including quantum dots that absorb light having a wavelength in a visible light region.

In an aspect, embodiments of the present disclosure provide a display device including a substrate, a subpixel, and a black bank.

The substrate can include a display area. The subpixel can be positioned on the substrate and positioned in the display area. The black bank can be positioned on the substrate.

The black bank can include a first opening corresponding to an emission area of the subpixel. The black bank can include quantum dots that absorb light having a wavelength in a visible light region.

According to embodiments of the present disclosure, there can be provided a display device capable of reducing external light reflectance by including a black bank which includes quantum dots that absorb light having a wavelength in a visible light region.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a system configuration diagram of a display device according to embodiments of the present disclosure;

FIG. 2 is a cross-sectional view of a display area of a display device according to a comparative example of the present disclosure;

FIGS. 3 and 4 are cross-sectional views of a display area of a display device according to embodiments of the present disclosure;

FIG. 5 is a schematic diagram illustrating quantum dots of a display device according to embodiments of the present disclosure;

FIG. 6 is a photomicrograph of the quantum dots of FIG. 5;

FIG. 7 is a graph of an absorption spectrum of the quantum dots of FIG. 5;

FIG. 8 is a schematic diagram illustrating quantum dots of a display device according to embodiments of the present disclosure;

FIG. 9 is a photomicrograph of the quantum dots of FIG. 8;

FIG. 10 is a graph of an emission spectrum of the quantum dots of FIG. 8;

FIG. 11 is a graph showing transmittance of a black bank of a display device according to embodiments of the present disclosure;

FIG. 12 is a graph showing an emission property of a black bank of a display device according to embodiments of the present disclosure;

FIG. 13 is a cross-sectional view of a display area of a display device according to embodiments of the present disclosure;

FIG. 14 is a plan view of the display area of the display device of FIG. 13;

FIG. 15 is a view illustrating the display device of FIG. 13 using infrared light;

FIG. 16 is a cross-sectional view of a display area of a display device according to embodiments of the present disclosure;

FIG. 17 is a plan view of the display area of the display device of FIG. 16; and

FIG. 18 is a view illustrating the display device of FIG. 16 using infrared light.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings. All the components of each display device according to all embodiments of the present disclosure are operatively coupled and configured.

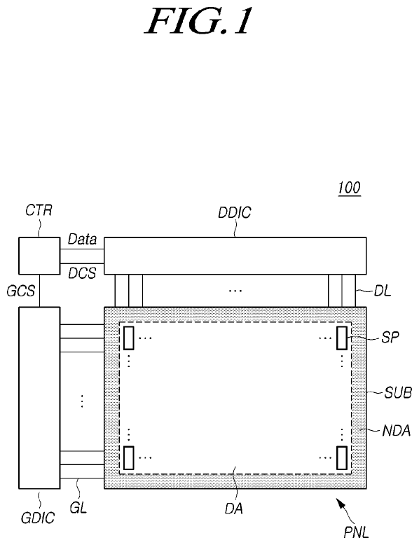

FIG. 1 is a system configuration diagram of a display device 100 according to embodiments of the present disclosure.

Referring to FIG. 1, the display device 100 according to embodiments of the present disclosure can include a display panel PNL and a driving circuit for driving the display panel PNL.

The driving circuit can include a data driving circuit DDIC and a gate driving circuit GDIC and can further include a controller CTR for controlling the data driving circuit DDIC and the gate driving circuit GDIC.

The display panel PNL can include a substrate SUB and signal lines such as a plurality of data lines DL and a plurality of gate lines GL disposed on the substrate SUB. The display panel PNL can include a plurality of subpixels SP connected to the plurality of data lines DL and the plurality of gate lines GL.

The display panel PNL can include a display area DA in which an image is displayed and a non-display area NDA in which an image is not displayed. In the display panel PNL, the plurality of subpixels SP for displaying an image can be disposed in the display area DA. In the non-display area NDA, the driving circuits DDIC, GDIC, and CTR can be electrically connected or mounted, and a pad portion to which an integrated circuit or a printed circuit is connected can also be disposed.

The data driving circuit DDIC can be a circuit for driving the plurality of data lines DL and can supply data voltages to the plurality of data lines DL. The gate driving circuit GDIC can be a circuit for driving the plurality of gate lines GL and can supply gate signals to the plurality of gate lines GL. The controller CTR can supply a data control signal DCS to the data driving circuit DDIC to control an operation timing of the data driving circuit DDIC. The controller CTR can supply a gate control signal GCS to the gate driving circuit GDIC to control an operation timing of the gate driving circuit GDIC.

The controller CTR can start a scan according to a timing set implemented in each frame. The controller CTR can convert input image data input from an external device to be suitable for a data signal format used by the data driving circuit DDIC, can output the converted image data to the data driving circuit DDIC, and can control data driving at an appropriate time according to the scan.

In order to control the gate driving circuit GDIC, the controller CTR can output various gate control signals (GCSs) including gate start pulse (GSP), gate shift clock (GSC), and gate output enable (GOE) signals.

In order to control the data driving circuit DDIC, the controller CTR can output various data control signals (DCSs) including source start pulse (SSP), source sampling clock (SSC), and source output enable (SOE) signals.

The controller CTR can be implemented as a separate component from the data driving circuit DDIC or can be integrated with the data driving circuit DDIC and implemented as an integrated circuit.

The data driving circuit DDIC receives image data DATA from the controller CTR and supplies data voltages to the plurality of data lines DL to drive the plurality of data lines DL. Here, the data driving circuit DDIC is also referred to as a source driving circuit.

The data driving circuit DDIC can include one or more source driver integrated circuits (SDICs).

For example, each SDIC can be connected to the display panel PNL in a tape automated bonding (TAB) type, can be connected to a bonding pad of the display panel PNL in a chip-on-glass (COG) or chip-on-panel (COP) type, or can be implemented as a chip-on-film (COF) type and connected to the display panel PNL.

The gate driving circuit GDIC can output a gate signal having a turn-on level voltage or a gate signal having a turn-off level voltage under the control of the controller CTR. The gate driving circuit GDIC can sequentially drive the plurality of gate lines GL by sequentially supplying a gate signal having a turn-on level voltage to the plurality of gate lines GL.

The gate driving circuit GDIC can be connected to the display panel PNL in a TAB type, can be connected to a bonding pad of the display panel PNL in a COG or COP type, or can be connected to the display panel PNL in a COF type. Alternatively, the gate driving circuit GDIC can be formed in the non-display area NDA of the display panel PNL in a gate-in-panel (GIP) type. The gate driving circuit GDIC can be disposed on or connected to the substrate SUB. For example, when the gate driving circuit GDIC is the GIP type, the gate driving circuit GDIC can be disposed in the non-display area NDA of the substrate SUB. When the gate driving circuit GDIC is the COG type, the COF type, or the like, the gate driving circuit GDIC can be connected to the substrate SUB.

Meanwhile, at least one driving circuit of the data driving circuit DDIC and the gate driving circuit GDIC can be disposed in the display area DA. For example, at least one driving circuit of the data driving circuit DDIC and the gate driving circuit GDIC can be disposed to not overlap the subpixels SP or can be disposed such that a portion or the entirety thereof overlaps the subpixels SP.

When a specific gate line GL is turned-on by the gate driving circuit GDIC, the data driving circuit DDIC can convert the image data DATA received from the controller CTR into an analog data voltage and can supply the analog data voltage to the plurality of data lines DL.

The data driving circuit DDIC can be connected to one side (for example, an upper or lower side) of the display panel PNL. According to a driving method, a panel design method, or the like, the data driving circuit DDIC can be connected to two sides (for example, the upper and lower sides) of the display panel PNL or can be connected to at least two side surfaces of four side surfaces of the display panel PNL.

The gate driving circuit GDIC can be connected to one side (for example, a left side or a right side) of the display panel PNL. According to a driving method, a panel design method, or the like, the gate driving circuit GDIC can be connected to two sides (for example, the left and right sides) of the display panel PNL or can be connected to at least two side surfaces of the four side surfaces of the display panel PNL.

The controller CTR can be a timing controller used in a typical display technology, can be a control device which can include the timing controller to further perform other control functions, can be a control device different from the timing controller, or can be a circuit inside a control device. The controller CTR can be implemented with various circuits or electronic components such as an integrated circuit (IC), a field programmable gate array (FPGA), an application specific integrated circuit (ASIC), and a processor.

The controller CTR can be mounted on a printed circuit board, a flexible printed circuit, or the like and can be electrically connected to the data driving circuit DDIC and the gate driving circuit GDIC through the printed circuit board or the flexible printed circuit.

The display device 100 according to the present embodiments can be a display including a backlight unit such as a liquid crystal display or can be a self-luminous display, such as an organic light-emitting diode (OLED) display, a quantum dot display, or a micro light-emitting diode (micro LED) display.

When the display device 100 according to the present embodiments is the OLED display, each subpixel SP can include an OLED, which emits light by itself, as a light-emitting element. When the display device 100 according to the present embodiments is the quantum dot display, each subpixel SP can include a light-emitting element made of quantum dots which are semiconductor crystals that emit light by themselves. When the display device 100 according to the present embodiments is the micro LED display, each subpixel SP can include a micro LED, which emits light by itself and is made based on an inorganic material, as a light-emitting element.

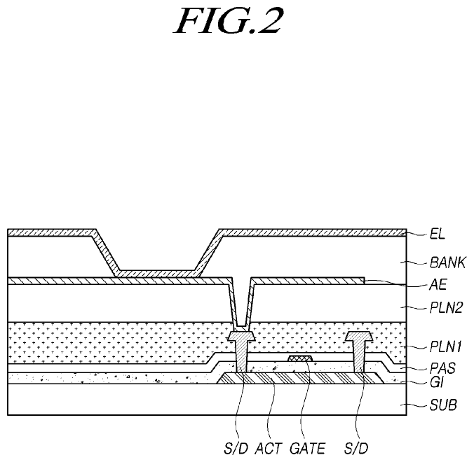

FIG. 2 is a cross-sectional view of a display area of a display device according to a comparative example of the present disclosure.

Referring to FIG. 2, the display device can include a substrate SUB, various components S/D, ACT, GATE, and AE of circuit elements, and a bank BANK.

A subpixel of the display device according to the comparative example can include a light-emitting element. The light-emitting element can include an anode AE.

The display device can include various components of the circuit elements S/D, ACT, GATE, and AE for driving the light-emitting element. The light-emitting element and the components of the circuit elements can be operated in response to electrical signals.

The light-emitting element and the components of the circuit elements can be required to have high electrical conductivity in order to efficiently transmit an electrical signal. For example, the anode, source/drain electrodes S/D, and a gate electrode GATE can include a metallic material to have high electrical conductivity.

In addition, in the display device, in order to use light generated from the light-emitting element as efficiently as possible, layers positioned in a path through which light travels can be transparent layers. For example, the bank BANK can also be a transparent layer.

However, when the bank BANK is a transparent layer, light incident from the outside of the display device can reach the light-emitting element and the components of the circuit elements of the display device and can be reflected by a layer including a metallic material. Due to such reflection, the display device has high reflectance, and there is a problem in that visibility is degraded under a condition in which external light is present.

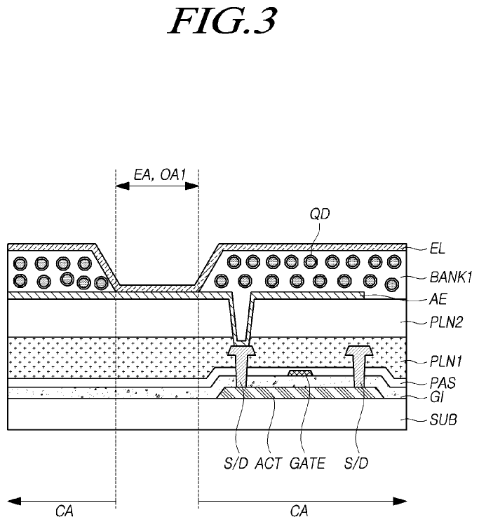

FIG. 3 is a cross-sectional view of a display area of a display device according to embodiments of the present disclosure.

Referring to FIG. 3, the display device according to embodiments can include a substrate SUB, a subpixel positioned on the substrate SUB, and a black bank BANK1 positioned on the substrate SUB. In addition, the display device can include various circuit components AE, EL, GATE, ACT, and S/D constituting a subpixel circuit and a plurality of insulating films GI, PAS, PLN1, and PLN2.

The substrate SUB can be a transistor substrate on which a transistor is formed.

The subpixel can include an emission area EA and a circuit area CA positioned outside the emission area EA. The circuit area CA can be an area positioned outside the emission area EA in a subpixel area and can be an area in which circuit elements constituting the subpixel circuit are positioned. Various conductive material layers S/D and GATE constituting the circuit elements of the subpixel can be positioned in the circuit area CA. For example, the transistor can be positioned in the circuit area CA. The transistor can include a gate electrode GATE, an active layer ACT, and source/drain electrodes S/D.

The black bank BANK1 can include a first opening OA1 corresponding to the emission area EA of the subpixel. The emission area EA of the subpixel can be an area from which light of the light-emitting element is emitted. The first opening OA1 corresponding to the emission area EA means that the first opening OA1 is formed such that light emitted from the emission area EA can be emitted to the outside of the display device through the first opening OA1.

The black bank BANK1 can include quantum dots QD. The quantum dots QD can be nanoparticles that emit light through photoluminescence (PL) in which electrons excited by external light transition from a conduction band to a valence band to emit light or through electroluminescence (EL) in which light is emitted by external charges.

The quantum dots QD can absorb light having a wavelength in a visible light region. Since the quantum dots QD absorb light having a wavelength in a visible light region, the black bank BANK1 can lower reflectance of the display device.

At least a portion of the black bank BANK1 can be positioned to overlap the circuit area CA. Since at least a portion of the black bank BANK1 is positioned to overlap the circuit area CA, light radiated onto the display device from the outside is prevented from being reflected from conductive material layers S/D, ACT, and GATE positioned in the circuit area CA, thereby allowing the display device to have low reflectance.

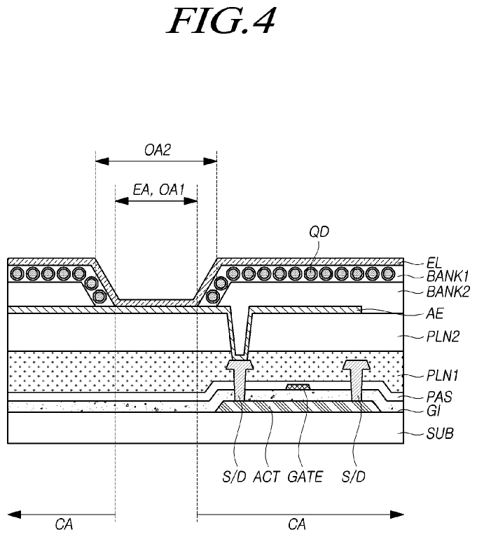

FIG. 4 is a cross-sectional view of a display area of a display device according to embodiments of the present disclosure.

In describing components of the display device according to embodiments shown in FIG. 4, components which are not specifically described differently can be the same as the above-described components of the display device according to embodiments shown in FIG. 3.

Referring to FIG. 4, the display device can include a bank BANK2 which is positioned on a substrate SUB, is positioned under a black bank BANK1, and includes a second opening OA2.

For example, the bank BANK2 can be transparent with respect to light having a wavelength in a visible light region. When the display device includes the transparent bank BANK2, the display device can have excellent efficiency and low reflectance.

A first opening OA1 can be formed in the second opening OA2.

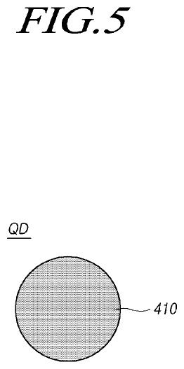

FIG. 5 is a schematic diagram illustrating quantum dots of a display device according to embodiments of the present disclosure.

Referring to FIG. 5, quantum dots QD can include particles of a core 410. The core 410 can include first semiconductor nanocrystals that absorb a wavelength in a visible light region.

The first semiconductor nanocrystal can include a group III-V compound. In the present disclosure, the term “group” can refer to a group of the periodic table of elements. For example, the group III-V compound can be boron phosphide (BP), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), indium antimonide (InSb), aluminum nitride (AlN), or boron nitride (BN).

For example, the first semiconductor nanocrystal can include indium (In) and arsenic (As).

A particle diameter of the quantum dots QD is not particularly limited. The particle diameter of the quantum dots QD can be selected within a particle diameter range that allows the quantum dots QD to have high absorbance with respect to light having a wavelength in a visible light region so that the display device has low reflectance.

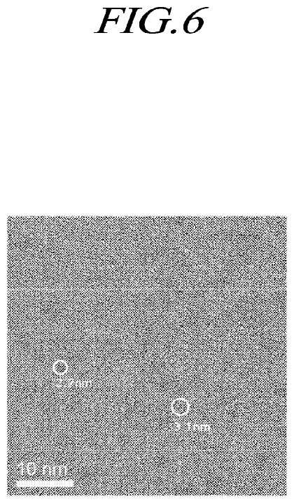

FIG. 6 is a photomicrograph of the quantum dots of FIG. 5.

Referring to FIG. 6, a particle diameter of the quantum dots QD of FIG. 5 can be in a range of 2 nm to 4 nm. When the particle diameter of the quantum dots QD is within the above-described range, a first absorbance peak of the quantum dots QD can be in a range of 900 nm to 980 nm.

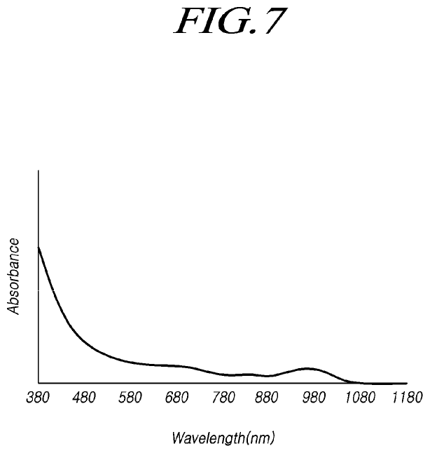

FIG. 7 is a graph of an absorption spectrum of the quantum dots of FIG. 5.

Referring to FIG. 7, it can be seen that the quantum dots of the display device according to embodiments have certain absorbance in a wavelength region of 380 nm to 700 nm, which is a wavelength in a visible light region. Accordingly, a black bank can have a property of absorbing visible light. In addition, since the quantum dots of FIG. 7 have a peak near 980 nm, it can be seen that the quantum dots have a particle diameter of 2 nm to 4 nm.

The quantum dots QD can include a second semiconductor nanocrystal that emits light in an infrared light region. When the quantum dots QD include the second semiconductor nanocrystal that emits light in an infrared light region, a black bank BANK1 can emit infrared light, and the display device can further include various optical and electronic devices using the emitted infrared light.

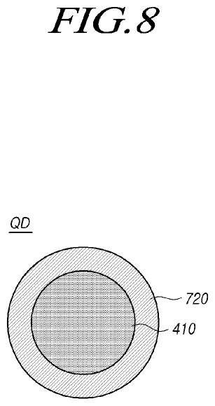

FIG. 8 is a schematic diagram illustrating quantum dots of a display device according to embodiments of the present disclosure.

Referring to FIG. 8, quantum dots QD can include a core 410 and a shell 720. For example, the quantum dots QD can have a multilayer structure having a core-shell structure.

The core 410 can include first semiconductor nanocrystals, and the shell 720 can include second semiconductor nanocrystals.

The second semiconductor nanocrystal can include a group II-VI compound. For example, the group II-VI compound can be lead sulfide (PbS), lead selenide (PbSe), magnesium sulfide (MgS), magnesium selenide (MgSe), magnesium telluride (MgTe), calcium sulfide (CaS), calcium selenide (CaSe), calcium telluride (CaTe), strontium sulfide (SrS), strontium selenide (SrSe), strontium telluride (SrTe), cadmium sulfide (CdS), cadmium selenide (CdSe), cadmium tellurium (CdTe), zinc sulfide (ZnS), zinc selenide (ZnSe), zinc telluride (ZnTe), mercury sulfide (HgS), mercury selenide (HgSe), or mercury telluride (HgTe).

The second semiconductor nanocrystal can include zinc (Zn) and selenium (Se).

Since the quantum dots QD include the shell 720 including the second semiconductor nanocrystal described above, light in an infrared light region can be emitted, and an electronic device using infrared light, which can be included in the display device, can apply infrared light.

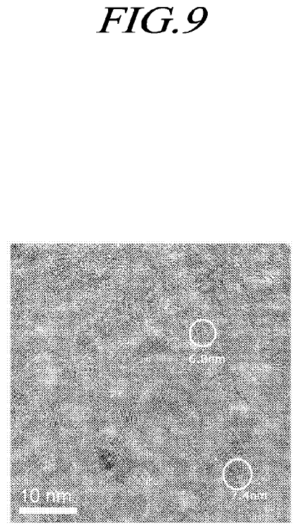

FIG. 9 is a photomicrograph of the quantum dots of FIG. 8.

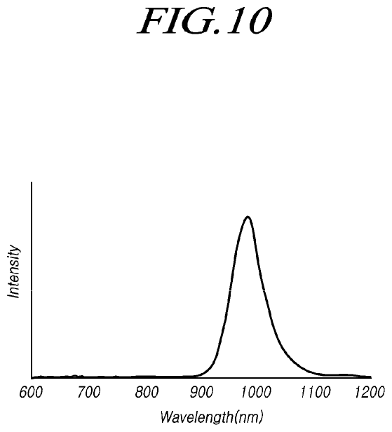

Referring to FIG. 9, a particle diameter of the quantum dots QD of FIG. 8 can be in a range of 6 nm to 8 nm. In the quantum dots QD, the core 410 can have a particle diameter of 2 nm to 4 nm, and the entire particle diameter including a particle diameter of the shell 720 can be in a range of 6 nm to 8 nm. When the particle diameter of the quantum dots QD satisfies the above-described range, the quantum dots can have an emission wavelength of 900 nm to 1,000 nm. FIG. 10 is a graph of an emission spectrum of the quantum dots of FIG. 8. FIG. 10 shows a PL emission spectrum of the quantum dots.

Referring to FIG. 10, it can be seen that the quantum dots emit light having a wavelength of 900 nm to 1,000 nm. Accordingly, a black bank including the quantum dots can absorb light having a wavelength in a visible light region to emit light having a wavelength in an infrared light region.

When the quantum dots emit infrared light having a wavelength of 900 nm to 1,000 nm, communication using infrared light can be very easy. Since it is known that energy of infrared light near a wavelength of 950 nm is considerably lower than energy in other wavelengths in a spectrum of sunlight, when light in a corresponding wavelength range is used, it is possible to minimize sunlight that acts as noise.

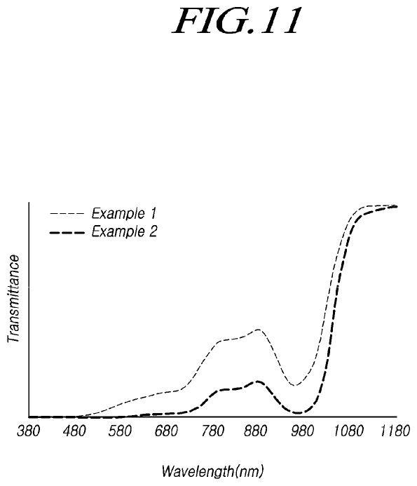

FIG. 11 is a graph showing transmittance of a black bank of a display device according to embodiments of the present disclosure.

In FIG. 11, Example 1 shows a result in which a transmittance measuring sample having a thickness of 1.51 μm was made of a black bank-forming composition to perform measurement, and Example 2 shows a result in which a transmittance measuring sample having a thickness of 2.9 μm was made of a black bank-forming composition to perform measurement.

Referring to FIG. 11, it can be seen that, in both Examples 1 and 2, low transmittance is maintained up to a wavelength of 380 nm to 780 nm, which is a wavelength in a visible light region. Accordingly, since the display device according to embodiments of the present disclosure includes the black bank having low visible light transmittance, external light reflectance can be reduced.

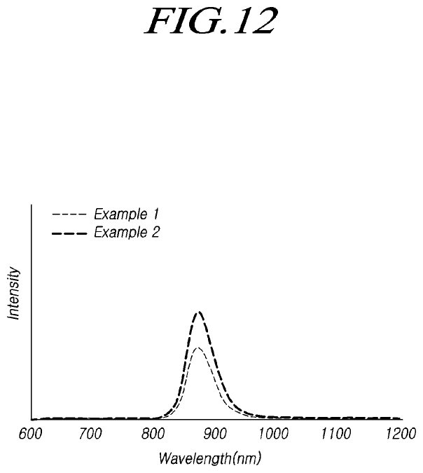

FIG. 12 is a graph showing an emission property of a black bank of a display device according to embodiments of the present disclosure.

Example 1 and Example 2 of FIG. 12 are the same as Examples 1 and 2 of FIG. 11. Referring to FIG. 12, it can be seen that a wavelength of PL emission is in an infrared light region in both Examples 1 and 2. Accordingly, the display device according to embodiments of the present disclosure can interact with another device using infrared light.

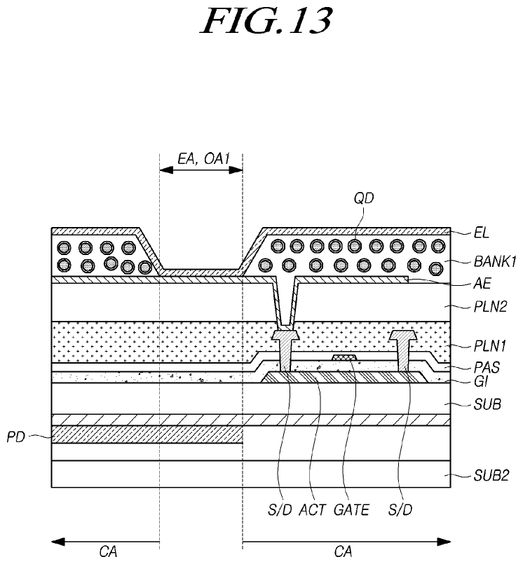

FIG. 13 is a cross-sectional view of a display area of a display device according to embodiments of the present disclosure.

In describing the display device according to embodiments shown in FIG. 13, components which are not specifically described differently can be the same as those of the display device according to embodiments described above with reference to FIG. 3.

Referring to FIG. 13, the display device can include a photodiode PD under a substrate SUB. The substrate SUB can be a transistor substrate on which a transistor and a light-emitting element are positioned.

The photodiode PD can be positioned on a substrate SUB2. The substrate SUB2 can be a photodiode substrate on which the photodiode PD is positioned.

The photodiode PD can be a photodiode that detects infrared light. Since the display device includes the photodiode PD that detects infrared light, it is possible to recognize that an object approaches using the photodiode PD.

The photodiode PD can be positioned in the circuit area CA and can be positioned to not overlap the transistor. Since the photodiode PD is positioned to not overlap the transistor, the photodiode PD can more effectively receive infrared light.

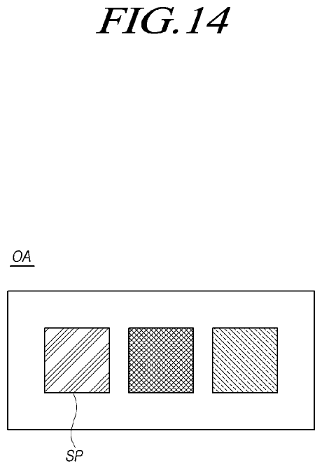

FIG. 14 is a plan view of the display area of the display device of FIG. 13.

Referring to FIG. 14, a plurality of subpixels SP are positioned in a display area DA. The photodiode can be positioned inside the subpixel SP. For example, the photodiode can be positioned to overlap the subpixel. When the photodiode is positioned inside the subpixel SP, a separate light-receiving pixel may not be formed, and the photodiode can also be disposed at a position at which a light-emitting pixel is disposed. Accordingly, the subpixel can be freely disposed in the display device, and a wide emission area can be secured.

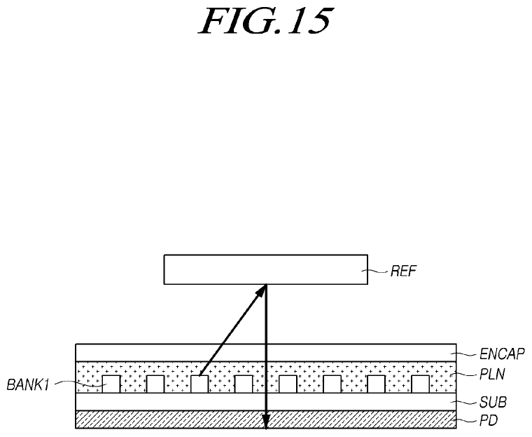

FIG. 15 is a view illustrating the display device of FIG. 13 using infrared light.

Referring to FIG. 15, infrared light emitted from a black bank BANK1 can be reflected by a reflector REF to reach the photodiode PD. Accordingly, when the display device includes the black bank BANK1, the use of the display device can be expanded to various uses such as use of a proximity sensor using infrared light.

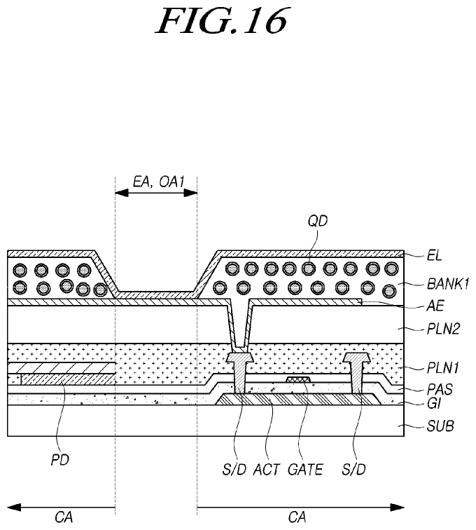

FIG. 16 is a cross-sectional view of a display area of a display device according to embodiments of the present disclosure.

In describing the display device according to embodiments shown in FIG. 16, components which are not specifically described differently can be the same as those of the display device according to embodiments described above with reference to FIG. 3.

Referring to FIG. 16, the display device can include a photodiode PD on a substrate SUB. The photodiode PD can be positioned under a black bank BANK1. The photodiode PD can be positioned between the substrate SUB and the black bank BANK1.

The photodiode PD can be a photodiode that detects infrared light. Since the display device includes the photodiode PD that detects infrared light, it is possible to recognize that an object approaches using the photodiode PD.

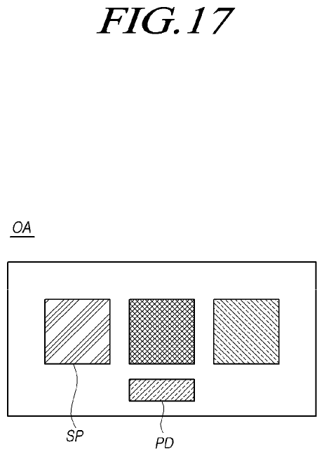

FIG. 17 is a plan view of the display area of the display device of FIG. 16.

Referring to FIG. 17, a plurality of subpixels SP are positioned in a display area DA. The subpixel SP is a light-emitting pixel. The photodiode PD can be positioned in a separate area that does not overlap the subpixel SP by forming electrodes separately from circuit elements constituting the subpixel SP which is a light-emitting pixel. When the photodiode PD is positioned to not overlap the subpixel SP which is the light-emitting pixel, the photodiode PD can more effectively receive infrared light.

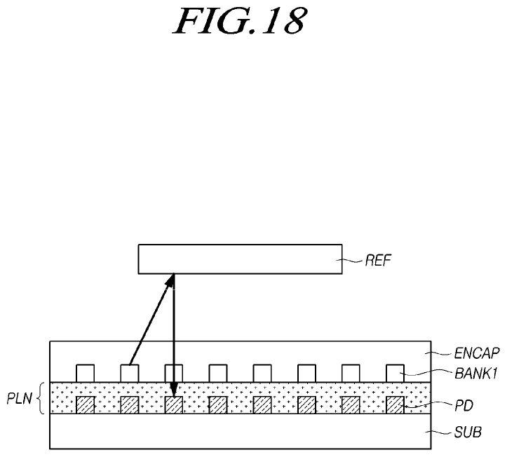

FIG. 18 is a view illustrating the display device of FIG. 16 using infrared light.

Referring to FIG. 18, infrared light emitted from the black bank BANK1 can be reflected by a reflector REF to reach the photodiode PD. Accordingly, when the display device includes the black bank BANK1, the use of the display device can be expanded to various uses such as use of a proximity sensor using infrared light.

The above-described embodiments of the present disclosure will be briefly described below.

According to embodiments of the present disclosure, there can be provided a display device 100 including a substrate SUB including a display area DA, a subpixel SP positioned on the substrate SUB and positioned in the display area DA, and a black bank BANK positioned on the substrate SUB.

The black bank BANK1 can include a first opening OA1 corresponding to an emission area EA of the subpixel SP. The black bank BANK1 can include quantum dots QD that absorb light having a wavelength in a visible light region.

The subpixel SP can include a circuit area CA positioned outside the emission area EA. At least a portion of the black bank BANK1 can be positioned to overlap the circuit area CA.

The display device 100 can include a transistor positioned in the circuit area CA.

The quantum dots QD can include first semiconductor nanocrystals that absorb the wavelength in the visible light region.

The quantum dots QD can include a core 410 and a shell 720. The core 410 can include the first semiconductor nanocrystals.

The first semiconductor nanocrystal can include a group III-V compound.

The first semiconductor nanocrystal can include indium (In) and arsenic (As).

The quantum dots QD can include a second semiconductor nanocrystal that emits light in an infrared light region.

The shell 720 can include the second semiconductor nanocrystal.

The second semiconductor nanocrystal can include a group II-VI compound.

The second semiconductor nanocrystal can include zinc (Zn) and selenium (Se).

The display device 100 can include a bank BANK2 positioned on the substrate SUB, positioned below the black bank BANK1, and including a second opening OA2.

The first opening OA1 can be formed in the second opening OA2.

The display device 100 can include a photodiode PD positioned under the substrate SUB and configured to detect infrared light. The photodiode PD can be positioned to overlap the subpixel SP.

The display device 100 can include a photodiode PD positioned on the substrate SUB, positioned under the black bank BANK1, and configured to detect infrared light. The photodiode PD can be positioned to not overlap the subpixel SP.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention. Thus, the scope of the present invention is not limited to the embodiments shown, but is to be accorded the widest scope consistent with the claims. The scope of protection of the present invention should be construed based on the following claims, and all technical ideas within the scope of equivalents thereof should be construed as being included within the scope of the present invention.

What is claimed is:

1. A display device comprising:
a substrate including a display area;
a subpixel positioned on the substrate and positioned in the display area; and
a black bank positioned on the substrate,
wherein the black bank includes:
a first opening corresponding to an emission area of the subpixel, and
quantum dots that absorb light having a wavelength in a visible light region.

2. The display device of claim 1, wherein:
the subpixel comprises a circuit area positioned outside the emission area; and
at least a portion of the black bank is positioned to overlap the circuit area.

3. The display device of claim 2, further comprising a transistor positioned in the circuit area.

4. The display device of claim 1, wherein the quantum dots comprise first semiconductor nanocrystals configured to absorb the wavelength in the visible light region.

5. The display device of claim 4, wherein:
the quantum dots comprise a core and a shell; and
the core comprises the first semiconductor nanocrystals.

6. The display device of claim 4, wherein each of the first semiconductor nanocrystals comprises a group III-V compound.

7. The display device of claim 6, wherein the first semiconductor nanocrystal comprises indium (In) and arsenic (As).

8. The display device of claim, 1, wherein the quantum dots comprise second semiconductor nanocrystals that emit light in an infraredlight region.

9. The display device of claim 8, wherein:
the quantum dots comprise a core and a shell; and
the shell comprises the second semiconductor nanocrystals.

10. The display device of claim 8, wherein each of the second semiconductor nanocrystals comprises a group II-VI compound.

11. The display device of claim 10, wherein the second semiconductor nanocrystal comprises zinc (Zn) and selenium (Se).

12. The display device of claim 1, further comprising a bank positioned on the substrate, positioned below the black bank, and including a second opening.

13. The display device of claim 12, wherein the first opening is positioned in the second opening.

14. The display device of claim 1, further comprising a photodiode positioned under the substrate and configured to detect infrared light.

15. The display device of claim 14, wherein the photodiode is positioned to overlap the subpixel.

16. The display device of claim 1, further comprising a photodiode positioned on the substrate, positioned under the black bank, and configured to detect infrared light.

17. The display device of claim, 16, wherein the photodiode is positioned to not overlap the subpixel.
